(19) United States
(12) Patent Application Publication
(10) Pub. No.: US 2023/0356355 A1
(43) Pub. Date: Nov. 9, 2023

(54) POLISHING HEAD WITH LOCAL INNER RING DOWNFORCE CONTROL

(71) Applicant: Applied Materials, Inc., Santa Clara, CA (US)

(72) Inventors: Jeonghoon Oh, Saratoga, CA (US); Brian J. Brown, Palo Alto, CA (US); Huanbo Zhang, San Jose, CA (US); Andrew Nagengast, Sunnyvale, CA (US); Steven M. Zuniga, Soquel, CA (US); Ekaterina A. Mikhaylichenko, San Jose, CA (US); Eric L. Lau, Santa Clara, CA (US); Jay Gurusamy, Santa Clara, CA (US); David J. Lischka, Austin, TX (US)

(73) Assignee: Applied Materials, Inc., Santa Clara, CA (US)

(21) Appl. No.: 17/735,674

(22) Filed: May 3, 2022

(51) Int. Cl. B24B 37/32; B24B 37/04

(52) U.S. Cl. CPC B24B 37/32; B24B 37/042

(57) ABSTRACT

Exemplary carrier heads for a chemical mechanical polishing apparatus may include a carrier body. The carrier heads may include a substrate mounting surface coupled with the carrier body. The carrier heads may include an inner ring that is sized and shaped to circumferentially surround a peripheral edge of a substrate positioned against the substrate mounting surface. The inner ring may be characterized by a first surface that faces the carrier body and a second surface opposite the first surface. The carrier heads may include at least one downforce control actuator disposed above the first surface of the inner ring at a discrete position about a circumference of the inner ring.

### TECHNICAL FIELD

The present technology relates to semiconductor systems, processes, and equipment. More specifically, the present technology relates to polishing film deposited on a substrate.

### BACKGROUND

An integrated circuit is typically formed on a substrate by the sequential deposition of conductive, semiconductive, and/or insulative layers on a silicon wafer. A variety of fabrication processes use the planarization of a layer on the substrate between processing steps. For example, for certain applications, e.g., polishing of a metal layer to form vias, plugs, and/or lines in the trenches of a patterned layer, an overlying layer is planarized until the top surface of a patterned layer is exposed. In other applications, e.g., planarization of a dielectric layer for photolithography, an overlying layer is polished until a desired thickness remains over the underlying layer.

Chemical mechanical polishing (CMP) is one common method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. Abrasive polishing slurry is typically supplied to the surface of the polishing pad.

One problem in CMP is uniformly polishing the entire surface of the substrate. Oftentimes, due to the design of CMP systems the regions of the polishing pad proximate the peripheral edges of the polishing pad may flex, which may lead to uneven polishing. Additionally, lateral forces on the substrate may be different at a leading edge and/or trailing edge of the substrate. As a result, film thickness may be uneven across one or more edge regions of the substrate. This film non-uniformity may cause lithography issues and may lead to a loss in die yield from a given substrate.

Thus, there is a need for improved systems and methods that can be used to polish substrates to generate a uniform film across an entire surface area of the substrate. These and other needs are addressed by the present technology.

### SUMMARY

Exemplary carrier heads for a chemical mechanical polishing apparatus may include a carrier body. The carrier heads may include a substrate mounting surface coupled with the carrier body. The carrier heads may include an inner ring that is sized and shaped to circumferentially surround a peripheral edge of a substrate positioned against the substrate mounting surface. The inner ring may be characterized by a first surface that faces the carrier body and a second surface opposite the first surface. The carrier heads may include an outer ring disposed radially outward of the inner ring. The carrier heads may include at least one downforce control actuator disposed above the first surface of the inner ring at a discrete position about a circumference of the inner ring.

In some embodiments, a magnitude of downforce applied by the at least one downforce control actuator to the discrete position of the inner ring may be variable. The at least one downforce control actuator may include a plurality of downforce control actuators. Each of the plurality of downforce control actuators may be disposed at a different discrete location about the circumference of the inner ring. The at least one downforce control actuator may be positioned proximate a trailing edge of the substrate. A magnitude of downforce applied by the at least one downforce control actuator to the discrete position of the inner ring may be variable during a single polishing operation. The at least one downforce control actuator may include a plunger that is in contact with the first surface of the inner ring. A downforce applied by the plunger may be driven by an air cylinder. The substrate mounting surface may include a flexible membrane. The outer ring may have an inner surface that is disposed against an outer surface of the inner ring.

Some embodiments of the present technology may encompass carrier heads for a chemical mechanical polishing apparatus. The carrier heads may include a carrier body. The carrier heads may include a substrate mounting surface coupled with the carrier body. The carrier heads may include an inner ring that is sized and shaped to circumferentially surround a peripheral edge of a substrate positioned against the substrate mounting surface. The inner ring may be characterized by a first surface that faces the carrier body and a second surface opposite the first surface. The carrier heads may include an outer ring disposed radially outward of the inner ring. The carrier heads may include a plurality of downforce control actuators disposed above the first surface of the inner ring. Each of the plurality of downforce control actuators may be located at a discrete position about a circumference of the inner ring.

In some embodiments, the plurality of downforce control actuators may be spaced apart at regular intervals about the circumference of the inner ring. A magnitude of downforce applied to the first surface of the inner ring may be different for at least one of the plurality of downforce control actuators. At least some of the plurality of downforce control actuators may be inactive during a given polishing operation. A magnitude of downforce applied by each of the plurality of downforce control actuators may be between or about 0 lbs and 10 lbs. The plurality of downforce control actuators may be disposed in an annular pattern that is concentric with a motor of the carrier head.

Some embodiments of the present technology may encompass methods of polishing a substrate. The methods may include flowing a polishing slurry from a slurry source to a polishing pad. The methods may include polishing a substrate atop the polishing pad. The methods may include applying a localized downforce to one or more discrete locations of an inner ring that retains the substrate within a carrier head while polishing the substrate.

In some embodiments, applying the localized downforce may include pressurizing an air cylinder coupled with a plunger to press the plunger against an upper surface of the inner ring. The methods may include adjusting a magnitude of downforce applied to at least one of the one or more discrete locations while the substrate is being polished. A magnitude of the localized downforce may be constant throughout a duration of the polishing. The one or more discrete locations may be proximate a trailing edge of the substrate. The methods may include determining a difference between a target polishing profile and an actual polishing profile. The methods may include adjusting the localized downforce for at least one of the one or more discrete locations of the inner ring based on the difference.

Such technology may provide numerous benefits over conventional systems and techniques. For example, the polishing heads described herein may help prevent excess polishing from occurring at the edge regions, and in particular the trailing edge and/or leading edge, of a substrate during polishing operations. This may enable the film thickness uniformity to be improved across the surface of the substrate, which may lead to increased die yield. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary polishing system according to some embodiments of the present technology.

FIG. 2 shows a schematic partial cross-sectional view of an exemplary carrier head according to some embodiments of the present technology.

FIG. 2A shows a schematic partial cross-sectional view of an inner ring of the carrier head of FIG. 2 according to some embodiments of the present technology.

FIG. 3 shows a schematic partial cross-sectional view of an exemplary carrier head according to some embodiments of the present technology.

FIG. 3A shows a schematic top plan view of the carrier head of FIG. 3A.

FIG. 4 is a flowchart of an exemplary method of polishing a substrate according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In conventional chemical mechanical polishing (CMP) operations it is often difficult to uniformly polish the surface of a substrate. Conventional CMP polishing involves a substrate being positioned face down on a polishing pad, with a carrier that holds the substrate against a rotating polishing pad. As the substrate is pushed across the polishing pad, the polishing pad often flexes near the edges of the substrate. Due to the stiffness of the substrate, the flexing and subsequent rebound of the polishing pad may lead to uneven concentrations of force near the edge regions of the substrate. For example, the pad rebound may cause a higher removal rate of material, which may often occur at the trailing edge of the substrate. Oftentimes, polishing may be uneven proximate the trailing edge and/or leading edge of the substrate, depending on the type of polishing operation being performed. These issues may result in non-uniformity issues that result in a lower die yield.

The present technology overcomes these issues with conventional polishing systems by using localized downforce control actuators to apply downforce to an inner retaining ring of the carrier head. The downforce may be used to control the flexing and/or rebound of the polishing pad to ensure help reduce uneven/excess polishing that may occur at one or more locations of the substrate. For example, the downforce may be applied to one or more locations of the inner ring that correspond to areas of the substrate that experience more pad rebound in order to reduce the rebound, and subsequently the polishing/removal rate proximate the areas of reduced rebound. In a particular embodiment, the downforce may be applied to the trailing edge and/or leading edge of the inner ring to counteract removal rate issues caused by pad flex and rebound proximate those regions. This may enable the downforce control at one or more discrete locations to be used as a localized tuning knob for the edge of the substrate. These techniques may be used in conjunction with conventional CMP systems to produce substrates with improved film thickness uniformity.

Although the remaining disclosure will routinely identify specific film polishing processes utilizing the disclosed technology, it will be readily understood that the systems and methods are equally applicable to a variety of other semiconductor processing operations and systems. Accordingly, the technology should not be considered to be so limited as for use with the described polishing systems or processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems, along with any number of modifications, some of which will be noted below.

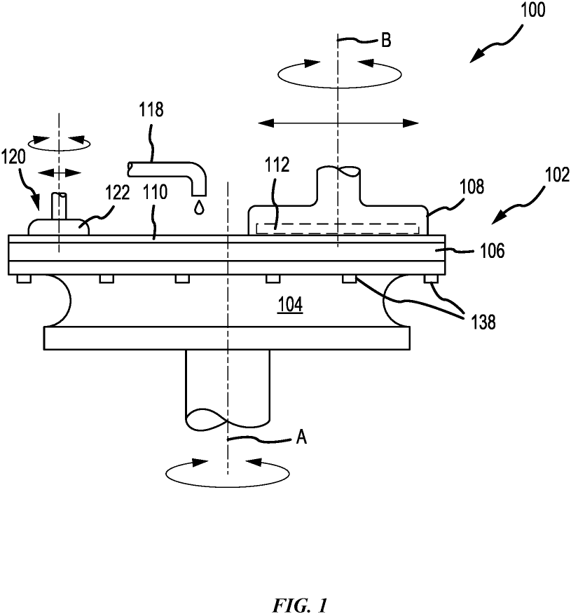

FIG. 1 shows a schematic cross-sectional view of an exemplary polishing system 100 according to some embodiments of the present technology. Polishing system 100 includes a platen assembly 102, which includes a lower platen 104 and an upper platen 106. Lower platen 104 may define an interior volume or cavity through which connections can be made, as well as in which may be included end-point detection equipment or other sensors or devices, such as eddy current sensors, optical sensors, or other components for monitoring polishing operations or components. For example, and as described further below, fluid couplings may be formed with lines extending through the lower platen 104, and which may access upper platen 106 through a backside of the upper platen. Platen assembly 102 may include a polishing pad 110 mounted on a first surface of the upper platen. A substrate carrier 108, or carrier head, may be disposed above the polishing pad 110 and may face the polishing pad 110. The platen assembly 102 may be rotatable about an axis A, while the substrate carrier 108 may be rotatable about an axis B. The substrate carrier may also be configured to sweep back and forth from an inner radius to an outer radius along the platen assembly, which may, in part, reduce uneven wear of the surface of the polishing pad 110. The polishing system 100 may also include a fluid delivery arm 118 positioned above the polishing pad 110, and which may be used to deliver polishing fluids, such as a polishing slurry, onto the polishing pad 110. Additionally, a pad conditioning assembly 120 may be disposed above the polishing pad 110, and may face the polishing pad 110.

In some embodiments of performing a chemical-mechanical polishing process, the rotating and/or sweeping substrate carrier 108 may exert a downforce against a substrate 112, which is shown in phantom and may be disposed within or coupled with the substrate carrier. The downward force applied may depress a material surface of the substrate 112 against the polishing pad 110 as the polishing pad 110 rotates about a central axis of the platen assembly. The interaction of the substrate 112 against the polishing pad 110 may occur in the presence of one or more polishing fluids delivered by the fluid delivery arm 118. A typical polishing fluid may include a slurry formed of an aqueous solution in which abrasive particles may be suspended. Often, the polishing fluid contains a pH adjuster and other chemically active components, such as an oxidizing agent, which may enable chemical mechanical polishing of the material surface of the substrate 112.

The pad conditioning assembly 120 may be operated to apply a fixed abrasive conditioning disk 122 against the surface of the polishing pad 110, which may be rotated as previously noted. The conditioning disk may be operated against the pad prior to, subsequent, or during polishing of the substrate 112. Conditioning the polishing pad 110 with the conditioning disk 122 may maintain the polishing pad 110 in a desired condition by abrading, rejuvenating, and removing polish byproducts and other debris from the polishing surface of the polishing pad 110. Upper platen 106 may be disposed on a mounting surface of the lower platen 104, and may be coupled with the lower platen 104 using a plurality of fasteners 138, such as extending through an annular flange shaped portion of the lower platen 104.

The polishing platen assembly 102, and thus the upper platen 106, may be suitably sized for any desired polishing system, and may be sized for a substrate of any diameter, including 200 mm, 300 mm, 450 mm, or greater. For example, a polishing platen assembly configured to polish 300 mm diameter substrates, may be characterized by a diameter of more than about 300 mm, such as between about 500 mm and about 1000 mm, or more than about 500 mm. The platen may be adjusted in diameter to accommodate substrates characterized by a larger or smaller diameter, or for a polishing platen 106 sized for concurrent polishing of multiple substrates. The upper platen 106 may be characterized by a thickness of between about 20 mm and about 150 mm, and may be characterized by a thickness of less than or about 100 mm, such as less than or about 80 mm, less than or about 60 mm, less than or about 40 mm, or less. In some embodiments, a ratio of a diameter to a thickness of the polishing platen 106 may be greater than or about 3:1, greater than or about 5:1, greater than or about 10:1, greater than or about 15:1, greater than or about 20:1, greater than or about 25:1, greater than or about 30:1, greater than or about 40:1, greater than or about 50:1, or more.

The upper platen and/or the lower platen may be formed of a suitably rigid, lightweight, and polishing fluid corrosion-resistant material, such as aluminum, an aluminum alloy, or stainless steel, although any number of materials may be used. Polishing pad 110 may be formed of any number of materials, including polymeric materials, such as polyurethane, a polycarbonate, fluoropolymers, polytetrafluoroethylene polyphenylene sulfide, or combinations of any of these or other materials. Additional materials may be or include open or closed cell foamed polymers, elastomers, felt, impregnated felt, plastics, or any other materials that may be compatible with the processing chemistries. It is to be understood that polishing system 100 is included to provide suitable reference to components discussed below, which may be incorporated in system 100, although the description of polishing system 100 is not intended to limit the present technology in any way, as embodiments of the present technology may be incorporated in any number of polishing systems that may benefit from the components and/or capabilities as described further below.

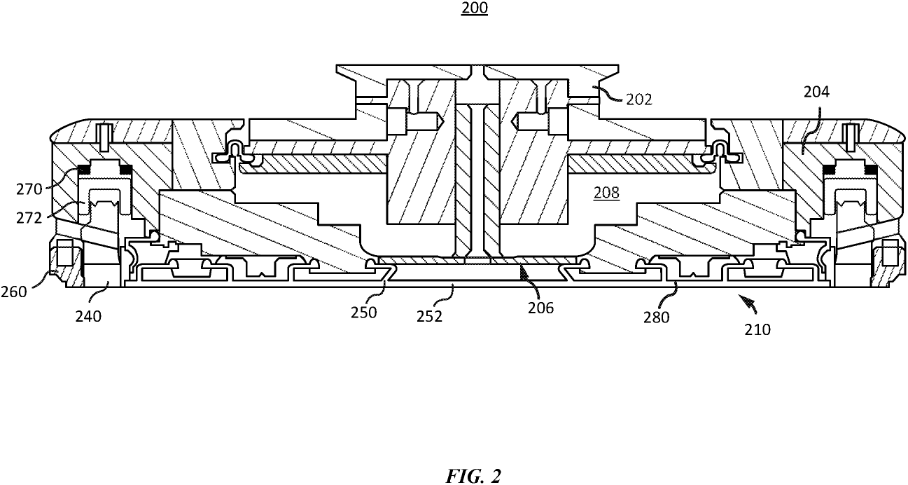

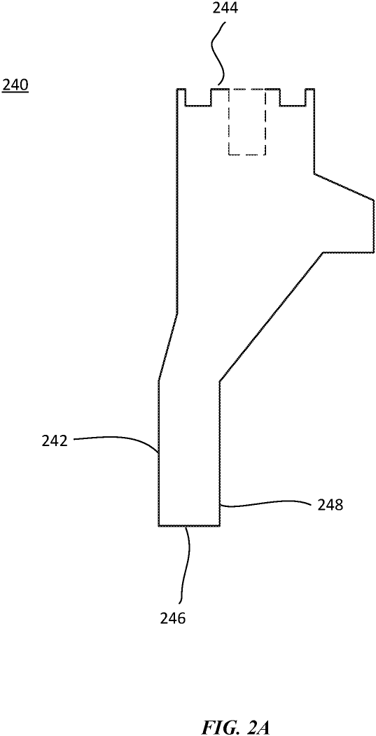

FIG. 2 illustrates a schematic cross-sectional side elevation view of an exemplary carrier head 200 according to some embodiments of the present technology. The carrier head 200 may show a partial view of the components being discussed and that may be incorporated in a polishing system, similar to polishing system 100. The carrier head 200 may be used as substrate carrier 108 in some embodiments. Carrier head 200 may include a housing 202, a base assembly 204 (housing 202 and base assembly 204 may be referred to as a carrier body), a gimbal mechanism 206 (which may be considered part of the base assembly 204), a loading chamber 208, an inner ring assembly including an inner ring 240 and a first flexible membrane 270 shaped to provide an annular chamber 272, an outer ring 260, and a substrate backing assembly 210, which may include a second flexible membrane 250 that defines a plurality of pressurizable chambers.

The housing 202 may generally be circular in shape and may be connected to a drive shaft to rotate therewith during polishing. There may be passages (not illustrated) extending through the housing 202 for pneumatic control of the carrier head 200. The base assembly 204 may be a vertically movable assembly located beneath the housing 202. The gimbal mechanism 206 may permit the base assembly 204 to gimbal relative to the housing 202, while preventing lateral motion of the base assembly 204 relative to the housing 202. The loading chamber 208 may be located between the housing 202 and the base assembly 204 to apply a load, i.e., a downward pressure or weight, to the base assembly 204. The vertical position of the base assembly 204 relative to a polishing pad (such as polishing pad 110) may be also controlled by the loading chamber 208. The substrate backing assembly 210 may include a flexible membrane 250 with a lower surface 252 that may provide a mounting surface for a substrate 280.

The substrate 280 can be held by the inner ring assembly, which may be clamped to a base assembly 204. The inner ring assembly may be constructed from inner ring 240 and a flexible membrane 250 shaped to provide an annular chamber 252. The inner ring 240 may be positioned beneath the flexible membrane 250 and may be configured to be secured to the flexible membrane 250.

As best illustrated in FIG. 2A, the inner ring 240 may be an annular body that has an inner surface 242, a first surface 244 that faces the carrier body, a second surface 246 (which may face and come into contact with the polishing pad) opposite the first surface 244, and an outer surface 248. A lower region of the inner surface 242, adjacent to the second surface 246, may be a generally vertical cylindrical surface, and may be configured to circumferentially surround the edge of substrate 280 to retain the substrate 280 during polishing. The lower region of the inner surface 242 may have an inner diameter just larger than the substrate diameter, e.g., about 1-2 mm larger than the substrate diameter, so as to accommodate positioning tolerances of the substrate loading system. An upper region of the inner surface 242 may be a generally vertical cylindrical surface, and may be slightly recessed relative to the lower region, e.g., the inner radial diameter of the upper region of the inner surface 242 may be greater than the inner radial diameter of the lower region of the inner surface 242. A tapered region may connect the lower region to the upper region in some embodiments.

A lower region of the outer surface 248, adjacent to the second surface 246, may be a vertical cylindrical surface. The portion of the inner ring 240 between the lower region of the inner surface 242 and the lower region of the outer surface 248 may provide a lower annular ring, e.g., with a width of 0.04 to 0.20 inches, e.g., 0.05 to 0.15 inches. An upper region of the outer surface 248, adjacent to the first surface 244, may be a vertical cylindrical surface, and the lower region of the outer surface 248 may be recessed relative to the upper region, e.g., the outer radial diameter of the upper region may be greater than the outer radial diameter of the lower region of the outer surface 248. The portion of the inner ring 240 between the upper region of the inner surface 242 and the upper region of the outer surface 248 may provide an upper annular ring that is wider than the lower annular ring. The outer radial diameter of the lower ring (i.e., the lower region of the outer surface 248) may be greater than the inner radial diameter of the upper ring (i.e., the upper region of the inner surface 242).

The second surface 246 of the inner ring 240 may be brought into contact with a polishing pad. At least a lower portion of the inner ring 240 that includes the second surface 246 may be formed of a material which is chemically inert in a CMP process, such as a plastic, e.g., polyphenylene sulfide (PPS). The lower portion should also be durable and have a low wear rate. In addition, the lower portion should be sufficiently compressible so that contact of the substrate edge against the inner ring does not cause the substrate to chip or crack. On the other hand, the lower portion should not be so elastic that downward pressure on the inner ring 240 causes the lower portion to extrude into the substrate receiving recess. In some embodiments, the upper portion of the inner ring 240 may be formed of a material that is more rigid than the lower portion. For example, the lower portion may be a plastic, e.g., PPS, and the upper portion may be a metal, e.g., stainless steel, molybdenum, or aluminum, or a ceramic, e.g., alumina.

In some implementations, the inner ring 240 may include one or more slurry transport channels formed in the lower surface. The slurry transport channels may extend from the inner diameter to the outer diameter of the lower ring portion to allow slurry to pass from the exterior to the interior of the inner ring 240 during polishing. The slurry transport channels may be evenly spaced around the inner ring in some embodiments. Each slurry transport channel may be offset at an angle, e.g., 45°, relative to the radius passing through the channel. The channels may have a width of about 0.125 inches.

In some implementations, the inner ring 240 may have one or more through holes that extend through the body of the inner ring 240 from the inner surface 242 to the outer surface 248 for allowing fluid, e.g., air or water, to pass from the interior to the exterior, or from the exterior to the interior, of the inner ring 240 during polishing. The through-holes may extend through the upper ring. The through holes may be evenly spaced around the inner ring 240 in some embodiments.

In some implementations the upper portion of the inner ring 240 may be wider at the lower surface than the upper surface. For example, the inner surface 242 may have a tapered region that slopes inwardly (i.e., having decreasing diameter) from top to bottom below a vertical region. The inner surface of the lower portion may be generally vertical. As the lower portion of the inner ring 240 wears during substrate polishing, the narrower upper inner surface of the inner ring 240 may prevent wear on the adjacent flexible membrane 270 that provides a substrate-mounting surface. In addition, in some implementations, the entire outer surface 248 of the inner ring 240 may be coated with a non-stick coating, e.g., parylene.

The flexible membrane 250 may be configured to be clamped above to base assembly 204 and secured below to inner ring 240. Positioning the flexible membrane between the inner ring 240 and the carrier head 200 may reduce or eliminate the impact of carrier distortion on the inner ring 240 which occurs when the ring 240 is directly secured to the carrier head 200. The elimination of this carrier distortion may reduce the uneven wear on the inner ring 240, reduce process variability at the substrate edge, and enable lower polishing pressures to be used, increasing ring lifetime. The flexible membrane 250 may be formed of a material that is elastic, allowing the membrane to flex under pressure. The elastic material may include silicone and other exemplary materials.

While the inner ring 240 may be configured to retain substrate 280 and provide active edge process control, the outer ring 260 may provide positioning or referencing of the carrier head 200 to the surface of the polishing pad. In addition, the outer ring 260 may contact and provide lateral referencing of the inner ring 240. The outer ring 260 may circumferentially surround inner ring 240. Like the inner ring 240, a lower surface of the outer ring 260 may be brought into contact with the polishing pad. The lower surface of the outer ring 260 may be smooth and wearable surface and may be selected so as to not abrade the polishing pad. An upper surface of the outer ring 260 may be secured to the base 204, e.g., the outer ring 260 may not vertically movable relative to the base 204. In some embodiments, an upper portion of the outer ring 260 may be formed of a material that is more rigid than a lower portion of the outer ring 260. For example, the lower portion may be a plastic, e.g., polyetheretherketone (PEEK), carbon filled PEEK, Teflon® filled PEEK, polyamidimid (PAI), or a composite material, while the upper portion may be a metal, e.g., stainless steel, molybdenum, or aluminum, or a ceramic, e.g., alumina. A portion of the outer ring 260 that includes the lower surface may be formed of a more rigid material than the portion of the inner ring 240 that includes the second surface 246. This may result in the outer ring 260 wearing at a lower rate than the inner ring 240. For example, the lower portion of the outer ring 260 may be a plastic that is harder than the plastic of the inner ring 240.

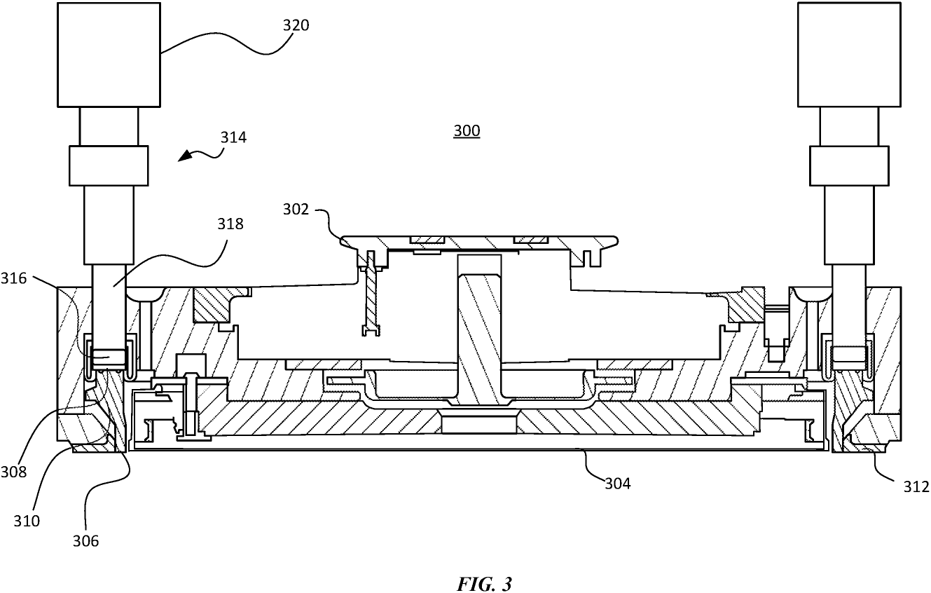

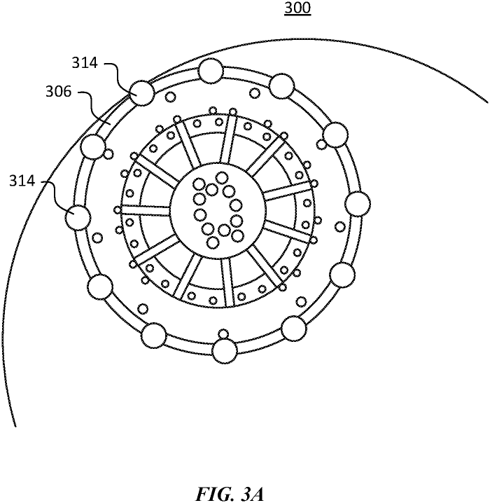

FIG. 3 illustrates a schematic cross-sectional side elevation view of an exemplary carrier head 300 according to some embodiments of the present technology. The carrier head 300 may be used to perform substrate polishing operations. FIG. 3 may show a partial view of the components being discussed and that may be incorporated in a chemical mechanical polishing system, such as polishing system 100 described herein. Carrier head 300 may be used as carrier head 108 and/or carrier head 200 in some embodiments, and may be understood to include any feature described in relation to carrier heads 108 and 200. Carrier head 300 may include a carrier body 302, which may include a housing and a base assembly in some embodiments, such as described in relation to FIG. 2. The carrier head 300 may include a substrate mounting surface 304, such as a flexible membrane, that may be coupled with a lower end of the carrier body 302. The substrate mounting surface 304 may be used to engage and apply downward pressure to a backside of a substrate during polishing operations.

Carrier head 300 may include an inner ring 306, which may be similar to inner ring 240 described above. For example, the inner ring 306 may be coupled with the carrier body 302 and may be engaged with a polishing pad. The inner ring 306 may be characterized by a first surface 308 (e.g., an upper surface) that faces the carrier body 302 and a second surface 310 (e.g., a lower surface) opposite the first surface 308. The inner ring 306 may be sized and shaped to circumferentially surround a peripheral edge of a substrate positioned against the substrate mounting surface 304. For example, a lowermost end (proximate the second surface 310) of the inner ring 306 may have an inner diameter that is greater than a diameter of a substrate being polished by a small amount (e.g., less than or about 5 mm, less than or about 4 mm, less than or about 3 mm, less than or about 2 mm, less than or about 1 mm, less than or about 0.5 mm, or less) such that the inner ring 306 may serve as a retaining ring to keep the substrate from sliding out of engagement with the substrate mounting surface 304 during polishing operations.

The second surface 310 may be brought into contact with the polishing pad (and abrasive slurry) while polishing the substrate. The second surface 310 may be formed of a material which is chemically inert in a CMP process, such as a plastic, e.g., polyphenylene sulfide (PPS). The inner ring 306 may be substantially rigid in a vertical direction (e.g., a direction that extends through the first surface 308 and the second surface 310), or may have some degree of flexibility (e.g., compressibility) in the vertical direction.

The carrier head 300 may include an outer ring 312, which may provide positioning or referencing of the carrier head 200 to the surface of the polishing pad. In addition, the outer ring 260 may contact and circumferentially surround inner ring 306. An upper surface of the outer ring 312 may be coupled with the carrier body 302 and a lower surface of the outer ring 312 may be brought into contact with the polishing pad. The lower surface of the outer ring 312 may be smooth and wearable surface and may be selected so as to not abrade the polishing pad. The outer ring 312 may help constrain movement and/or deformation of the lower end of the inner 306 during polishing operations.

Carrier head 300 may include one or more downforce control actuators 314. Each downforce control actuator 314 may be disposed in alignment with the first surface 308 of the inner ring 306 at a discrete position about the circumference of the inner ring 306. For example, each downforce control actuator 314 may be positioned above the first surface 308 of the inner ring 306 such that the downforce control actuator 314 may selectively apply a downforce to the first surface 308 at the discrete location. The downforce may press the second surface 310 of the inner ring 306 into the polishing pad proximate the peripheral edge of the substrate. This may cause an amount of pad flex and/or rebound to be altered in the area proximate the respective downforce control actuator 314. For example, at areas of the substrate (such as the trailing edge and/or leading edge) that may experience higher pad rebound (and subsequently higher removal rates), the downforce may be applied to the inner ring 306, which may reduce the amount of pad rebound. This may help reduce and/or eliminate areas of higher or lower removal rate, and may help contribute to a more uniform film thickness profile across the surface of the substrate.

The operation (e.g., on/active or off/inactive) of each downforce control actuator 314 and/or a magnitude of the downforce applied to the inner ring 306 at each downforce control actuator 314 may be controlled to alter the amount of flex and/or rebound of the polishing pad in order to adjust and/or otherwise control the polishing removal rate across the substrate, and in particular, near edges regions (such as the leading and/or trailing edge) of the substrate. In some embodiments, each downforce control actuator 314 may provide a downforce of between or about 0 kg and 5 kg. For example, the downforce applied may be less than or about 5 kg, less than or about 4.5 kg, less than or about 4 kg, less than or about 3.5 kg, less than or about 3 kg, less than or about 2.5 kg, less than or about 2 kg, less than or about 1.5 kg, less than or about 1 kg, less than or about 0.5 kg, or less. A magnitude of the downforce applied by each of the downforce control actuators 314 may be constant and/or variable in some embodiments. For example, the downforce may be adjusted to have a predetermined magnitude for a given polishing recipe. In some embodiments, the magnitude of the downforce may be adjusted and/or switched on/off during the polishing operation. For example, the magnitude of the downforce may be increased and/or decreased in the middle of the polishing operation. Such adaptive downforce control may be used to help improve polishing rate/film uniformity and/or otherwise achieve a desired polishing rate/film thickness profile.

In some embodiments including multiple downforce control actuators 314, each downforce control actuators 314 may apply a same magnitude of downforce, while in other embodiments at least one downforce control actuator 314 applies a different magnitude (including zero) downforce as at least one other downforce control actuator 314. In some embodiments, each downforce control actuator 314 may deliver a different magnitude of downforce. Each of the downforce control actuators 314 may be independently controllable such that an operational state (i.e., on or off) and/or a magnitude of downforce applied by the given downforce control actuator 314 may be controlled independent of each of the other downforce control actuators 314. For example, all or some of the downforce control actuators 314 may be active or inactive during a given polishing operation to generate a desired film thickness profile.

Each downforce control actuator 314 may be in the form of a linear actuator that is configured to selectively apply a constant and/or variable magnitude of downforce to a discrete location. The linear actuator may take numerous forms, such as, but not limited to, mechanical and/or electromechanical actuators (e.g., leadscrews, screw jacks, ball screws, roller screws, cam actuators, a bellow with guide system, a flexure/lever system, etc.) hydraulic actuators, and/or pneumatic actuators. In a particular embodiment, the downforce control actuators 314 may each include a plunger 316 that is disposed in an air cylinder 318. The air cylinder 318 may be fluidly coupled with a pneumatic pressure source 320, which may selectively control a flow of air to the air cylinder 318 to control the pressure within the air cylinder 318. The pressure within the air cylinder 318 may cause the plunger 316 to press down upon the first surface 308 of the inner ring 306 and control a downforce applied from the second surface 310 of the inner ring 306 to the polishing pad, with higher pressures within the air cylinder 318 causing greater downforces applied by the plunger 316. In some embodiments, the plunger 316 (or other force applicator of the downforce control actuator 314) may be in direct contact with the first surface 308 of the inner ring 306, while in other embodiments one or more intervening components may be disposed between the force applicator to transfer downforce from the downforce control actuator 314 to the inner ring 306.

Each downforce control actuator 314 may apply any downforce to the inner ring 308 over a contact area, which may be determined by a contact surface of a force applicator of the downforce control actuator 314 and/or a contact surface of an intervening component that contacts and transfers the downforce to the inner ring 308. In a particular embodiment, the contact area may be defined by a size of an arc of the inner ring 308 that is actually contacted by a down force transmitting component. The contact area for each downforce control actuator 314 may be less than or about 10 degrees of the circumference of the inner ring 308, less than or about 9 degrees, less than or about 8 degrees, less than or about 7 degrees, less than or about 6 degrees, less than or about 5 degrees, less than or about 4 degrees, less than or about 3 degrees, less than or about 2 degrees, less than or about 1 degree, less than or about 0.5 degrees, or less. In some embodiments, the downforce applied by a given downforce control actuator 314 may be concentrated substantially to the portion of the inner ring 306 disposed beneath and contacted by the downforce control actuator 314. In other embodiments, the downforce applied by a given downforce control actuator 314 may be distributed circumferentially along the inner ring 306 so as to affect a larger arc of the inner ring 306. For example, the downforce applied by a given downforce control actuator 314 may be distributed circumferentially along at least or about 0.5 degrees of the inner ring 306 beyond the contact area (in one or both directions), at least or about 1 degree, at least or about 2 degrees, at least or about 5 degrees, at least or about 10 degrees, at least or about 15 degrees, at least or about 20 degrees, at least or about 30 degrees, or more. The spread of the downforce may, in some embodiments, be controlled by a vertical elasticity and/or compressibility of the inner ring 306. For example, a more rigid inner ring 306 may spread the downforce out over a larger circumferential area than a more elastic/compressible inner ring 306. Some embodiments may utilize a more elastic/compressible inner ring 306 to provide a more precisely controllable amount of downforce control to counteract any polishing rate uniformity issues associated with pad flex and/or pad rebound.

In some embodiments, a single downforce control actuator 314 may be included within the carrier head 300. For example, it may be determined that only a single region (such as, but not limited to, the trailing edge or leading edge) of a substrate is experiencing edge uniformity issues during polishing. The single downforce control actuator 314 may be positioned at or proximate (e.g., within or about 20 degrees, within or about 15 degrees, within or about 10 degrees, within or about 5 degrees, within or about 3 degrees, within or about 1 degree, or less) the region experiencing the edge uniformity issues. In other embodiments, the carrier head 300 may include multiple downforce control actuators 314. For example, the carrier head 300 may include at least or about two downforce control actuators 314, at least or about three downforce control actuators 314, at least or about four downforce control actuators 314, at least or about five downforce control actuators 314, at least or about six downforce control actuators 314, at least or about seven downforce control actuators 314, at least or about eight downforce control actuators 314, at least or about nine downforce control actuators 314, at least or about ten downforce control actuators 314, at least or about eleven downforce control actuators 314, at least or about twelve downforce control actuators 314, or more.

In embodiments with multiple downforce control actuators 314, each downforce control actuator 314 may be disposed at a different discrete location about the circumference of the inner ring 306. The downforce control actuators 314 may be spaced at regular and/or irregular intervals about the circumference of the inner ring 306. For example, as illustrated in the schematic top plan view of FIG. 3A, in some embodiments the downforce control actuators 314 may be disposed in an annular pattern that is concentric with the inner ring 306, the carrier head 300, and a motor that drives rotation of the carrier head 300. In other embodiments, the downforce control actuators 314 may be arranged only about one or more regions of the circumference of the inner ring 306. For example, the downforce control actuators 314 may be provided in regions likely to have uneven polishing rates due to polishing pad flex/rebound. For example, the downforce control actuators 314 may only be disposed at and/or proximate the trailing edge and/or leading edge regions of the substrate/inner ring 306. It will be appreciated that where multiple downforce control actuators 314 are included in a carrier head 300, any number of the downforce control actuators 314 (including zero) may be active during a given polishing operation. The operational status and/or magnitude of downforce applied by each downforce control actuator 314 may be customized for (and possibly varied within) a given polishing operation to generate a desired film thickness profile.

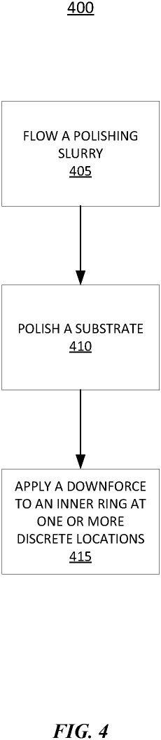

FIG. 4 shows exemplary operations in a method 400 for polishing a substrate according to some embodiments of the present technology. Method 400 may be performed using carrier head, such as carrier head 108, 200, or 300 described herein. Method 400 may include operations prior to the substrate polishing in some embodiments. For example, prior to the polishing, a substrate may have one or more deposition and/or etching operations performed as well as any planarization or other process operations performed. Method 400 may include a number of operations that may be performed automatically within a system to limit manual interaction, and to provide increased efficiency and precision over manual operations. Method 400 may be performed as part of or in conjunction with a conventional CMP polishing process.

Method 400 may include flowing a polishing slurry from a slurry source to a polishing pad at operation 405. The substrate may be polished atop the polishing pad at operation 410. For example, the substrate may be positioned within a carrier head that rotates and/or translates (or sweeps) the substrate about the surface of the polishing pad such that abrasive particles within the polishing slurry may gradually remove material from a surface of the substrate in a desired pattern and/or to achieve a desired film thickness profile. In some embodiments, in addition to or alternatively to the carrier head rotating and/or translating, the polishing pad may rotate and/or translate. A back surface of the substrate may be positioned against a substrate mounting surface, such as a flexible membrane, that may be used to apply pressure to the back surface of the substrate during polishing operations. The substrate may be retained in a desired position relative to the carrier head and flexible membrane using an inner ring that is disposed radially outward of the substrate. To counteract uneven polishing rates that may occur due to the flexing and/or rebound of the polishing pad that occurs as the substrate and the surface of the polishing pad are moved relative to one another, a localized downforce may be applied to one or more discrete locations (such as at or proximate the trailing edge and/or leading edge) of the inner ring at operation 415. This downward force may increase pad flex and/or reduce pad rebound, and may be used to generate a more uniform polishing rate across the surface of the substrate, and in particular at edge regions, such as at or near the trailing edge and/or leading edge of the substrate.

Applying the localized downforce may be performed using one or more downforce control actuators, such as downforce control actuators 314. For example, in a particular embodiment each downforce control actuator 314 may include a plunger that is driven by an air cylinder. The air cylinder may be pressurized, such as by delivering air or other fluid from a pneumatic source to the air cylinder, which may force the plunger to apply downward force (directly or indirectly) to an upper surface of the inner ring. This downward force may press a portion of the inner ring proximate the downforce control actuator 314 downward into the polishing pad to increase flex and/or reduce rebound in a given area. A magnitude of the downforce may be constant in some embodiments, while in other embodiments the magnitude of the downforce may be varied or otherwise adjusted at one or more discrete locations while the substrate is being polished.

In some embodiments, the method 400 may optionally include determining a difference between a target polishing profile and an actual polishing profile. For example, a polishing duration, pattern (e.g., sweeping motion, rotation, etc.), and/or other factors may be selected to polish the substrate to a desired, or target, film thickness profile (which may be substantially uniform thickness in some embodiments). However, due to factors such as pad flex and pad rebound, there may be uneven polishing rates at certain regions of the substrate, such as near the trailing edge and/or leading edge. Measurements of a polished substrate may be taken to determine whether there are any differences between the actual film thickness profile and the target film thickness profile the polishing operation is intended to achieve. Based on an analysis of such differences, the localized downforce for at least one of the downforce control actuators may be adjusted. For example, if it is determined that excess wear (e.g., too thin a film) is present on a trailing edge of the substrate, an increased magnitude of localized downforce may be applied at or proximate the trailing edge using one or more downforce control actuators, which may reduce the pad rebound within the region, and subsequently reduce the removal rate. This may help the polishing rate be more uniform across the surface of the substrate. In particular, a magnitude of downforces for one or more discrete locations of the inner ring may be identified by experimentation. For example, multiple test substrates may be polished using different combinations of downforces applied to one of more discrete locations of the inner ring, but otherwise using the same process parameters for polishing of device substrates. The uniformity of the test substrates in the area near the edge (or other regions) may be measured, e.g., using a stand-alone metrology unit, and the combination of pressures that provided the best polishing uniformity (or otherwise closest to a target film thickness profile) may be selected for later polishing of device substrates.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A carrier head for a chemical mechanical polishing apparatus, comprising:
a carrier body;
a substrate mounting surface coupled with the carrier body;
an inner ring that is sized and shaped to circumferentially surround a peripheral edge of a substrate positioned against the substrate mounting surface, the inner ring being characterized by a first surface that faces the carrier body and a second surface opposite the first surface;
an outer ring disposed radially outward of the inner ring; and
at least one downforce control actuator disposed above the first surface of the inner ring at a discrete position about a circumference of the inner ring.

2. The carrier head for a chemical mechanical polishing apparatus of claim 1, wherein:
a magnitude of downforce applied by the at least one downforce control actuator to the discrete position of the inner ring is variable.

3. The carrier head for a chemical mechanical polishing apparatus of claim 1, wherein:
the at least one downforce control actuator comprises a plurality of downforce control actuators, each of the plurality of downforce control actuators being disposed at a different discrete location about the circumference of the inner ring.

4. The carrier head for a chemical mechanical polishing apparatus of claim 1, wherein:
the at least one downforce control actuator is positioned proximate a trailing edge of the substrate.

5. The carrier head for a chemical mechanical polishing apparatus of claim 1, wherein:
a magnitude of downforce applied by the at least one downforce control actuator to the discrete position of the inner ring is variable during a single polishing operation.

6. The carrier head for a chemical mechanical polishing apparatus of claim 1, wherein:
the at least one downforce control actuator comprises a plunger that is in contact with the first surface of the inner ring; and
a downforce applied by the plunger is driven by an air cylinder.

7. The carrier head for a chemical mechanical polishing apparatus of claim 1, wherein:
the substrate mounting surface comprises a flexible membrane.

8. The carrier head for a chemical mechanical polishing apparatus of claim 1, wherein:
the outer ring has an inner surface that is disposed against an outer surface of the inner ring.

9. A carrier head for a chemical mechanical polishing apparatus, comprising:
a carrier body;
a substrate mounting surface coupled with the carrier body;
an inner ring that is sized and shaped to circumferentially surround a peripheral edge of a substrate positioned against the substrate mounting surface, the inner ring being characterized by a first surface that faces the carrier body and a second surface opposite the first surface;
an outer ring disposed radially outward of the inner ring; and
a plurality of downforce control actuators disposed above the first surface of the inner ring, each of the plurality of downforce control actuators being located at a discrete position about a circumference of the inner ring.

10. The carrier head for a chemical mechanical polishing apparatus of claim 9, wherein:
the plurality of downforce control actuators are spaced apart at regular intervals about the circumference of the inner ring.

11. The carrier head for a chemical mechanical polishing apparatus of claim 9, wherein:
a magnitude of downforce applied to the first surface of the inner ring is different for at least one of the plurality of downforce control actuators.

12. The carrier head for a chemical mechanical polishing apparatus of claim 9, wherein:
at least some of the plurality of downforce control actuators are inactive during a given polishing operation.

13. The carrier head for a chemical mechanical polishing apparatus of claim 9, wherein:
a magnitude of downforce applied by each of the plurality of downforce control actuators is between or about 0 lbs and 10 lbs.

14. The carrier head for a chemical mechanical polishing apparatus of claim 9, wherein:
the plurality of downforce control actuators are disposed in an annular pattern that is concentric with a motor of the carrier head.

15. A method of polishing a substrate, comprising:
flowing a polishing slurry from a slurry source to a polishing pad;
polishing a substrate atop the polishing pad; and
applying a localized downforce to one or more discrete locations of an inner ring that retains the substrate within a carrier head while polishing the substrate.

16. The method of polishing a substrate of claim 15, wherein:
applying the localized downforce comprises pressurizing an air cylinder coupled with a plunger to press the plunger against an upper surface of the inner ring.

17. The method of polishing a substrate of claim 15, further comprising:
adjusting a magnitude of downforce applied to at least one of the one or more discrete locations while the substrate is being polished.

18. The method of polishing a substrate of claim 15, wherein:
a magnitude of the localized downforce is constant throughout a duration of the polishing.

19. The method of polishing a substrate of claim 15, wherein:
the one or more discrete locations are proximate a trailing edge of the substrate.

20. The method of polishing a substrate of claim 15, further comprising:
determining a difference between a target polishing profile and an actual polishing profile; and
adjusting the localized downforce for at least one of the one or more discrete locations of the inner ring based on the difference.
